(19) United States
(12) Patent Application Publication
(10) Pub. No.: US 2026/0183810 A1
(43) Pub. Date: Jul. 2, 2026

(54) SUBSTRATE PROCESSING DEVICE, SUBSTRATE PROCESSING METHOD, AND STORAGE MEDIUM

(71) Applicant: EBARA CORPORATION, Tokyo (JP)

(72) Inventors: Kohei SATO, Tokyo (JP); Ryota SANOKI, Tokyo (JP)

(21) Appl. No.: 19/426,427

(22) Filed: Dec. 19, 2025

(30) Foreign Application Priority Data
Dec. 26, 2024 (JP) 2024-229878

(51) Int. Cl. B08B 13/00; B08B 3/00; G01F 1/661; H10P 72/00

(52) U.S. Cl. CPC B08B 13/00; B08B 3/003; G01F 1/661; H10P 72/0406

(57) ABSTRACT

To supply a more stable fine bubble liquid to a device. A substrate processing device includes: a first substrate detection unit that detects a substrate in a first module to be used in a first process; a bubble measurement unit that measures a bubble amount in piping, which supplies a fine bubble liquid to a second module to be used in a second process subsequent to the first process, in response to detection of the substrate by the first substrate detection unit; and a control unit that controls the bubble amount in accordance with a measurement result by the bubble measurement unit.

### BACKGROUND OF THE DISCLOSURE

### Field of the Invention

The present disclosure relates to a substrate processing device, a substrate processing method, and a storage medium.

### Description of the Related Art

A technique for stabilizing a polishing process for a substrate by supplying a fine bubble liquid onto a polishing pad has conventionally been known (see Japanese Patent Laid-Open No. 2023-134918).

### SUMMARY

A substrate processing device according to one aspect of the present disclosure includes:
   a first substrate detection unit that detects a substrate in a first module to be used in a first process;
   a bubble measurement unit that measures a bubble amount in piping, which supplies a fine bubble liquid to a second module to be used in a second process subsequent to the first process, in response to detection of the substrate by the first substrate detection unit; and
   a control unit that controls the bubble amount in accordance with a measurement result by the bubble measurement unit.
[2] As for the substrate processing device according to one aspect of the present disclosure, in the above [1],
   the bubble measurement unit has a light emission unit, which emits light toward the fine bubble liquid in the piping, and a light reception unit, which receives the light transmitted through the fine bubble liquid, and measures the bubble amount in accordance with a received light amount of light received by the light reception unit.
[3] As for the substrate processing device according to one aspect of the present disclosure, in the above [2],
   the control unit uses, as the bubble amount, a result of conversion of the received light amount into the number of bubbles.
[4] As for the substrate processing device according to one aspect of the present disclosure, in any one of the above [1] to [3],
   the control unit controls the bubble amount in a case where the bubble amount measured by the bubble measurement unit exceeds a reference range.
[5] In any one of the above [1] to [4], the substrate processing device according to one aspect of the present disclosure further includes
   a second substrate detection unit that detects the substrate in the second module, and
   in a case where the second substrate detection unit detects the substrate, the control unit does not control the bubble amount and notifies that the bubble amount is unstable.
[6] A substrate processing method according to one aspect of the present disclosure includes:
   detecting a substrate in a first module to be used in a first process;
   measuring a bubble amount in piping, which supplies a fine bubble liquid to a second module to be used in a second process subsequent to the first process, in response to detection of the substrate in the first module; and
   controlling the bubble amount in accordance with a measurement result of the bubble amount.
[7] A program according to one aspect of the present disclosure is
   a program for causing a computer to execute a substrate processing method, the substrate processing method including:
   detecting a substrate in a first module to be used in a first process;
   measuring a bubble amount in piping, which supplies a fine bubble liquid to a second module to be used in a second process subsequent to the first process, in response to detection of the substrate in the first module; and
   controlling the bubble amount in accordance with a measurement result of the bubble amount.

A storage medium according to one aspect of the present disclosure is
a computer-readable storage medium storing the program of the above [7].

### BRIEF DESCRIPTION OF THE DRAWINGS

FIG. 1 is a diagram illustrating one example of an outline configuration of a substrate processing device according to the present embodiment;

FIG. 2 is a diagram illustrating one example of a function configuration of the substrate processing device according to the present embodiment;

FIG. 3 is a diagram illustrating one example of a hardware configuration of a substrate processing device according to the present embodiment;

FIG. 4 is a diagram for explaining measurement of a bubble amount of a fine bubble liquid;

FIG. 5 is a diagram illustrating one example of a relationship between a received light amount measured by a bubble measurement unit and the number of bubbles;

FIG. 6 is a diagram for explaining examples of reference ranges of the bubble amount;

FIG. 7 is a flowchart illustrating one example of a substrate process by using the fine bubble liquid;

FIG. 8 is a flowchart illustrating one example of a dummy dispensation process of the fine bubble liquid; and

FIG. 9 is a flowchart illustrating one example of control of the bubble amount of the fine bubble liquid.

### DETAILED DESCRIPTION OF THE DISCLOSURE

Each embodiment will hereinafter be described with reference to the drawings. However, unnecessarily detailed descriptions might be skipped. For example, detailed descriptions about already known items and repeated descriptions about substantially the same configurations might be skipped. This is for avoiding a situation where the following descriptions become unnecessarily redundant and is for facilitating understanding by persons having ordinary skill in the art.

### Configuration of Substrate Processing Device

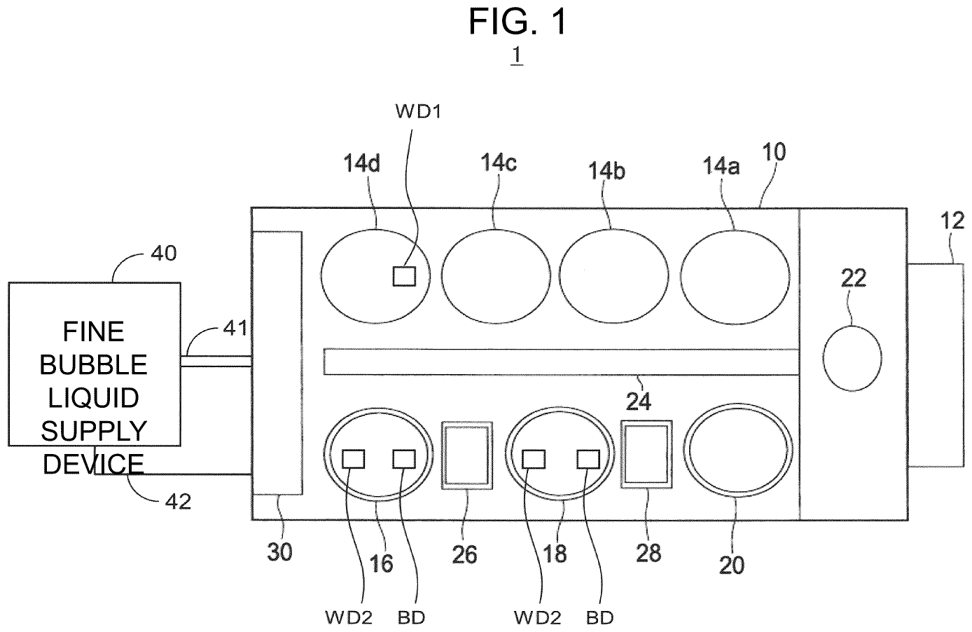

As illustrated in FIG. 1, a substrate processing device 1 of the present embodiment has a housing 10 having a generally rectangular shape and a load port 12 on which a substrate cassette stocking a large number of substrates W is placed. The load port 12 is arranged adjacent to the housing 10. In the load port 12, an open cassette, a standard mechanical interface (SMIF) pod, or a front opening unified pod (FOUP) can be mounted. Each of the SMIF pod and the FOUP is a sealed container which houses the substrate cassette in its inside, covers the substrate cassette by a partition wall, and can thereby maintain an environment independent of an external space. Examples of the substrate W may include semiconductor wafers and so forth.

A plurality (four in a setting illustrated in FIG. 1) of polishing modules 14a to 14d, a first cleaning module 16 and a second cleaning module 18 which clean the polished substrate W, and a drying module 20 which dries the cleaned substrate W are housed inside the housing 10. The polishing modules 14a to 14d are arrayed in a longitudinal direction of the substrate processing device 1, and the cleaning modules 16 and 18 and the drying module 20 are also arrayed in the longitudinal direction of the substrate processing device 1. The substrate processing device 1 of the present embodiment can perform a polishing process for various substrates W in manufacturing steps for a semiconductor wafer having a diameter of 300 or 450 mm, a flat panel, an image sensor such as a complementary metal oxide semiconductor (CMOS) and a charge coupled device (CCD), and a magnetic film in a magnetoresistive random access memory (MRAM).

A first conveyance robot 22 is arranged in a region that is surrounded by the load port 12 and the polishing module 14a and drying module 20 which are positioned on the load port 12 side. A conveyance module 24 is arranged in parallel with the polishing modules 14a to 14d, the cleaning modules 16 and 18, and the drying module 20. The first conveyance robot 22 accepts the substrate W, which is to be polished, from the load port 12, hands over it to the conveyance module 24, takes out the dried substrate W from the drying module 20, and returns it to the load port 12.

A second conveyance robot 26, which hands over the substrate W between the first cleaning module 16 and the second cleaning module 18, is arranged between the first cleaning module 16 and the second cleaning module 18, and a third conveyance robot 28, which hands over the substrate W between the second cleaning module 18 and the drying module 20, is arranged between the second cleaning module 18 and the drying module 20. In addition, in the inside of the housing 10, an overall control unit 30 is arranged which controls motions of each apparatus of the substrate processing device. In the present embodiment, a description will be made by using a setting in which the overall control unit 30 is arranged in the inside of the housing 10; however, this is not restrictive, and the overall control unit 30 may be arranged on the outside of the housing 10, or the overall control unit 30 may be provided in a remote location.

A fine bubble liquid supply device 40 supplies a fine bubble liquid to the substrate processing device 1 via piping 41. The fine bubble liquid supplied to the substrate processing device 1 is supplied to each of the modules (for example, the polishing modules 14a to 14d and the cleaning modules 16 and 18) of the substrate processing device 1 and is sprayed from a spray nozzle, which is not illustrated, in a predetermined step.

The fine bubble liquid supply device 40 can supply a microbubble liquid and an ultra-fine bubble liquid. In the present specification, the fine bubble liquid is a superordinate concept that includes the microbubble liquid and the ultra-fine bubble liquid, and a bubble diameter of the ultra-fine bubble liquid is smaller than that of the microbubble liquid.

The polishing module 14d is provided with a first substrate detection apparatus (first substrate detection unit) WD1 which detects the substrate W. When the first substrate detection apparatus WD1 detects the substrate W, a detection signal is sent to the overall control unit 30.

Each of the cleaning modules 16 and 18 is provided with a second substrate detection apparatus (second substrate detection unit) WD2 which detects the substrate W, and when the second substrate detection apparatus WD2 detects the substrate W, a detection signal is sent to the overall control unit 30.

Each of the cleaning modules 16 and 18 is provided with a bubble measurement apparatus (bubble measurement unit) BD which measures a bubble amount contained in the fine bubble liquid supplied from the fine bubble liquid supply device 40. A measurement result (signal value) measured by the bubble measurement apparatus BD is sent to the overall control unit 30.

Each of the cleaning modules 16 and 18 includes a spray nozzle which sprays (dispenses) the fine bubble liquid supplied from the fine bubble liquid supply device 40. Accordingly, the cleaning modules 16 and 18 can clean the substrate W by using the fine bubble liquid.

Note that in the present embodiment, as one example, a description will be made about an example where the fine bubble liquid is supplied to the cleaning modules 16 and 18 of the substrate processing device 1, whereas the fine bubble liquid may be supplied to the polishing modules 14a to 14d. Specifically, the fine bubble liquid may be supplied to piping for an atomizer or piping for slurry in the polishing modules 14a to 14d, and a liquid mixture in which the fine bubble liquid is mixed may thereby be supplied from a spray nozzle, which is arranged in a spatial position of the polishing modules 14a to 14d, to a polishing table. In this case, the spray nozzle, the second substrate detection apparatus WD2, and the bubble measurement apparatus BD may be provided in the polishing modules 14a to 14d, and the first substrate detection apparatus WD1 may be provided in the vicinity of the first conveyance robot 22 or in the vicinity of the load port 12.

### Function Configuration

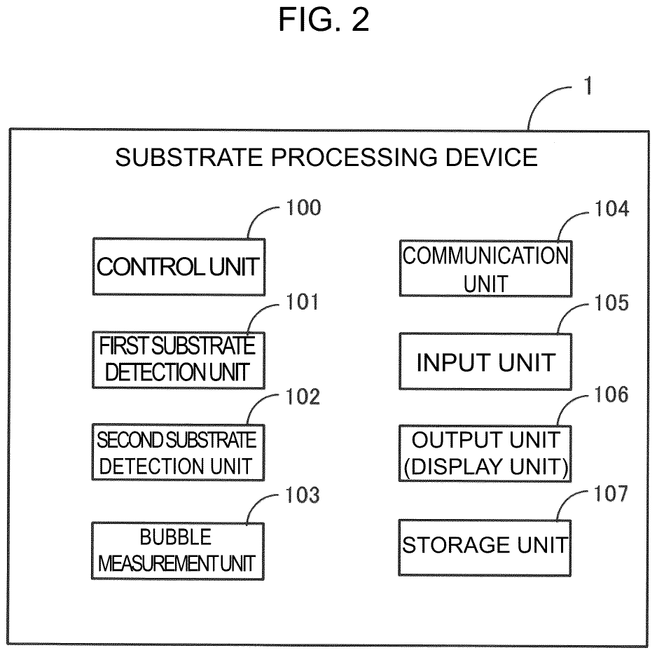

FIG. 2 is a diagram illustrating one example of a function configuration of the substrate processing device 1 according to the present embodiment. As illustrated in FIG. 2, the substrate processing device 1 has a control unit 100, a first substrate detection unit 101, a second substrate detection unit 102, a bubble measurement unit 103, a communication unit 104, an input unit 105, an output unit (display unit) 106, and a storage unit 107. Note that in FIG. 2, a function unit performing each function can be considered as means performing each function.

The control unit 100 performs a dummy dispensation process, which will be described later, in accordance with a measurement result by the bubble measurement unit 103. Here, dummy dispensation is referred to a process for adjusting the bubble amount of the fine bubble liquid while spraying the fine bubble liquid, as advance preparation made before a substrate process using the fine bubble liquid is actually performed.

The first substrate detection unit 101 detects the substrate W in a module (first module) to be used in a step (first process) prior to a step (second process) of the substrate process using the fine bubble liquid. Specifically, in a case where the step of the substrate process using the fine bubble liquid is a cleaning step, the first substrate detection unit 101 detects the substrate W in a polishing module to be used in a polishing step as a step prior to the cleaning step. In a case where the step of the substrate process using the fine bubble liquid is the polishing step, the first substrate detection unit 101 detects the substrate W in a conveyance module (the first conveyance robot 22 or the load port 12) to be used in a conveyance step as a step prior to the polishing step.

The second substrate detection unit 102 detects the substrate W in a module (second module) to be used in a step (second process) of the substrate process using the fine bubble liquid. Specifically, in a case where the step of the substrate process using the fine bubble liquid is the cleaning process, the second substrate detection unit 102 detects the substrate W in the cleaning module. In a case where the step of the substrate process using the fine bubble liquid is the polishing step, the second substrate detection unit 102 detects the substrate W in the polishing module.

The bubble measurement unit 103 measures the bubble amount in piping for supplying the fine bubble liquid to the module to be used in the step of the substrate process using the fine bubble liquid.

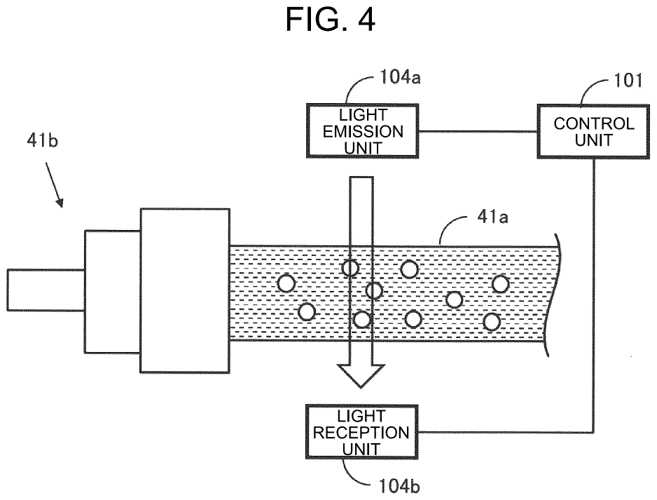

FIG. 4 is a diagram for explaining a measurement method about the bubble amount of the fine bubble liquid by the bubble measurement unit 103. As illustrated in FIG. 4, the bubble measurement unit 103 has a light emission unit 104a, which emits light toward the fine bubble liquid in piping 41a, and a light reception unit 104b, which receives light transmitted through the fine bubble liquid, and measures the bubble amount in accordance with a received light amount of light received by the light reception unit 104b. When the bubble amount in the fine bubble liquid increases, light is scattered by bubbles, and the fine bubble liquid becomes turbid and white. Thus, in response to an increase in the bubble amount in the fine bubble liquid, the received light amount of light received by the light reception unit 104b decreases. Note that it is preferable to provide the bubble measurement unit 103 in the vicinity of a spray nozzle 41b. Accordingly, the bubble amount of the fine bubble liquid can be controlled by using the bubble amount at a time immediately before the fine bubble liquid is actually sprayed onto the module.

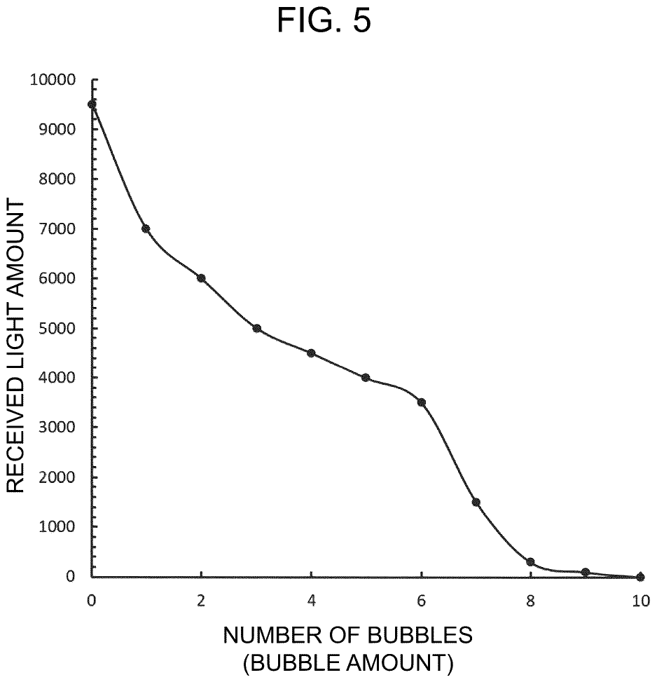

FIG. 5 is a diagram illustrating one example of a relationship between the received light amount measured by the bubble measurement unit 103 and the number of bubbles (bubble amount) in the fine bubble liquid. For example, as illustrated in FIG. 5, data can be stored in the storage unit 107 as a database or a function, and the bubble amount can thereby be obtained from the received light amount measured by the bubble measurement unit 103. Note that the bubble amount is not limited to the number of bubbles and may be a bubble density or the like.

Returning to FIG. 2, the communication unit 104 is a communication interface between the substrate processing device 1 and other devices. The communication unit 104 transmits and receives information between the communication unit 104 and a server or a terminal device via a network.

The input unit 105 is a component that allows a user (including a user or a maintenance person of the substrate processing device 1) of the substrate processing device 1 to input information and is a keyboard, a mouse, a touch panel, a microphone, a gesture input device, or the like, for example.

The output unit (display unit) 106 is an interface which outputs various kinds of information (images or sounds) from the substrate processing device 1 to the user and is a video display device (display unit) such as a liquid crystal display or a speaker, for example. When the output unit 106 is formed as the display unit, a GUI for accepting an operation from the user is displayed on the display unit.

The storage unit 107 is a data storage such as an internal memory, an external memory (such as an SD memory card), or the like, for example. The storage unit 107 stores various kinds of data to be handled by the control unit 100, various kinds of information that the communication unit 104 downloads from a server via a network, and so forth. Note that the storage unit 107 may not necessarily be provided in the substrate processing device 1, and a part of or the whole storage unit 107 may be provided in another device which is connected to the substrate processing device 1 via the network to be capable of communicating with the substrate processing device 1.

### Hardware Configuration

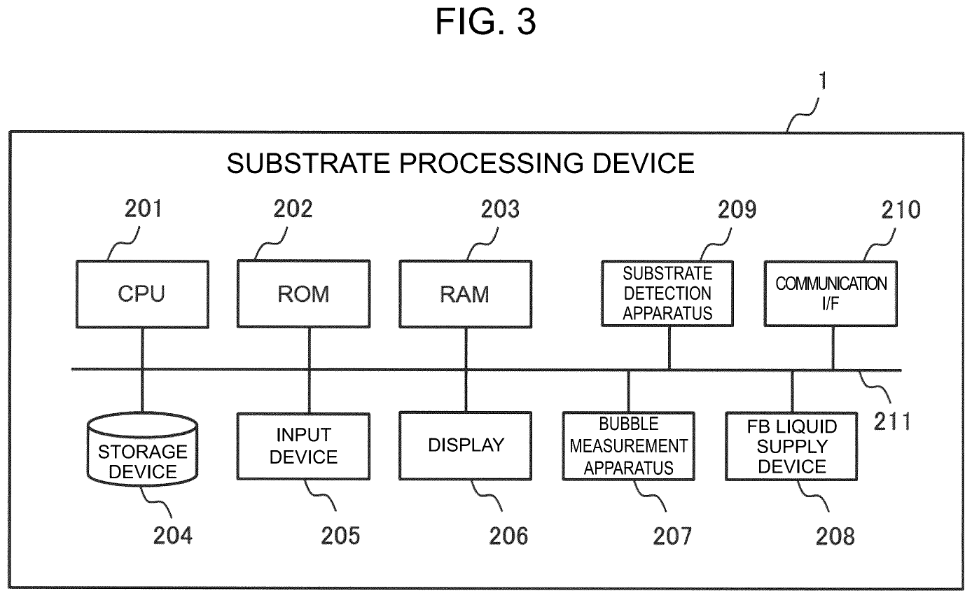

Next, a description will be made about a hardware configuration of the substrate processing device 1 according to the present embodiment. FIG. 3 is a block diagram illustrating one example of the hardware configuration of the substrate processing device 1 according to the present embodiment.

In the substrate processing device 1, a CPU 201 is a processing device which controls an action of the whole substrate processing device 1. A ROM 202 is a non-volatile memory which stores control programs to be executed by the CPU 201 and various kinds of data. A RAM 203 is a volatile memory which is used for a loading area or a working area of programs to be executed by the CPU 201. The storage device 204 is storage means for storing various kinds of information and may be the storage means which is built in a main body of the substrate processing device 1 or may be the storage means from which a storage medium is detachable. The input device 205 is a device that allows the user of the substrate processing device 1 to input information and is a keyboard, a mouse, a touch panel, a microphone, or the like, for example. A display 206 is a display device which displays various kinds of information (such as a user interface). A bubble measurement apparatus 207 is a measurement apparatus which measures the bubble amount in piping for supplying the fine bubble liquid to the module to be used in the step of the substrate process using the fine bubble liquid. An FB liquid supply device 208 is a device which supplies the fine bubble liquid to the substrate processing device 1. A substrate detection apparatus 209 is a detection apparatus (including a first substrate detection apparatus and a second substrate detection apparatus) for detecting the substrate W. A communication I/F (interface) 210 is an interface for connection to other devices and networks which are not illustrated. A bus 211 is a bus line which mutually connects the above configuration elements.

### One Example of Action

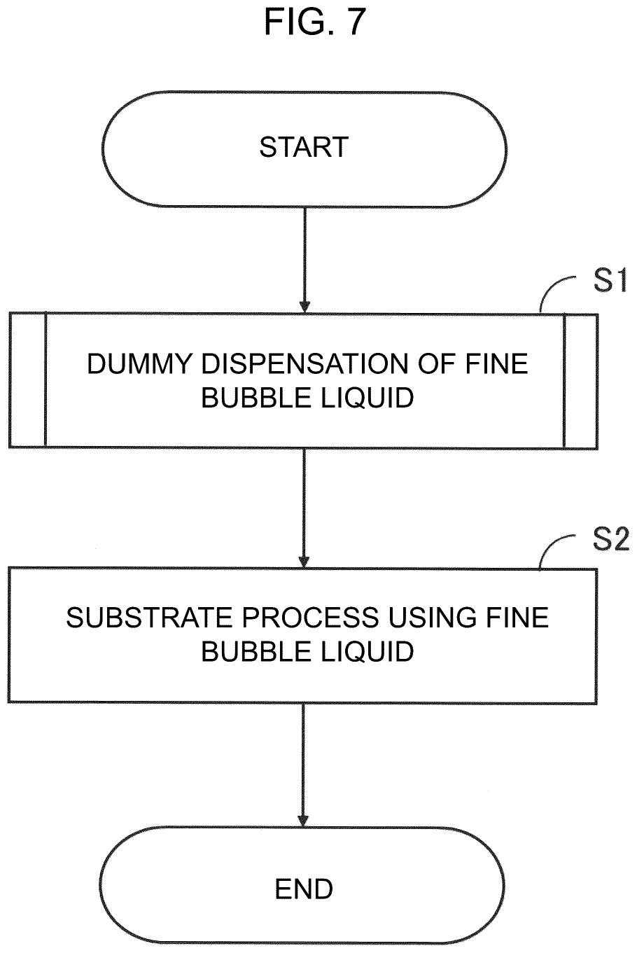

Next, a description will be made about one example of an action of the substrate processing device 1 according to the present embodiment. FIG. 7 is a flowchart illustrating one example of an action of the substrate process using the fine bubble liquid in the substrate processing device 1.

First, the control unit 100 performs the dummy dispensation process of the fine bubble liquid (step S1). For example, in a case where the substrate W is cleaned by using the fine bubble liquid, adjustment of the fine bubble liquid (dummy dispensation process) is performed before the substrate W is cleaned by actually using the fine bubble liquid.

When the adjustment of the fine bubble liquid (dummy dispensation process) is completed, the control unit 100 performs the substrate process by actually using the fine bubble liquid (step S2).

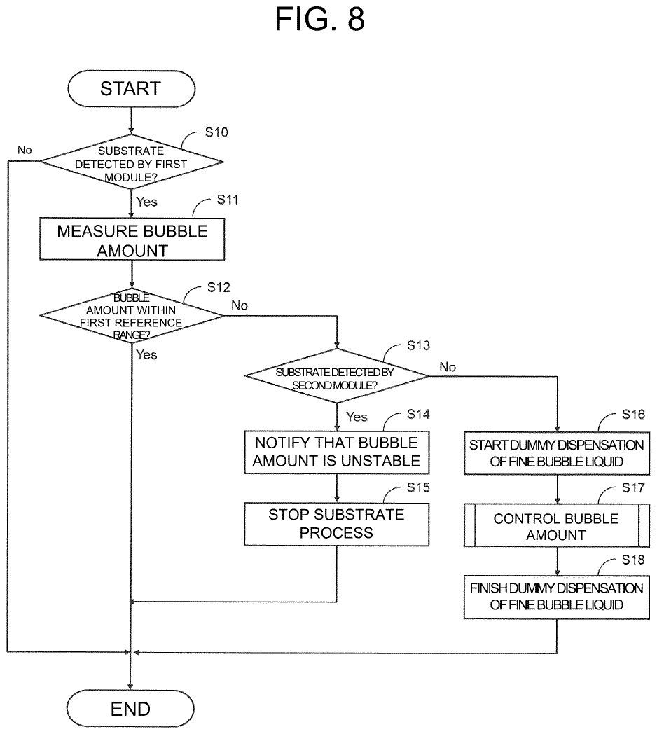

Next, a description will be made about an action of the dummy dispensation process by the substrate processing device 1 according to the present embodiment. FIG. 8 is a flowchart illustrating one example of the action of the dummy dispensation process (step S1) in FIG. 7.

First, the control unit 100 determines whether or not the first substrate detection unit 101 detects the substrate W in the first module to be used in the step prior to the step of the substrate process using the fine bubble liquid (step S10). In a case where the determination is affirmative, the process progresses to step S11. In a case where the determination is negative, the dummy dispensation process is finished.

In a case where the first substrate detection unit 101 detects the substrate W (in a case where the determination in step S10 is affirmative), the control unit 100 performs measurement of the bubble amount in the piping, through which the fine bubble liquid is supplied, by the bubble measurement unit 103 (step S11). In such a manner, the bubble amount of the fine bubble liquid is measured by using, as a trigger, detection of the substrate W in the step prior to the step using the fine bubble liquid, and it thereby becomes possible to adjust the bubble amount of the fine bubble liquid before the substrate is actually processed using the fine bubble liquid.

Next, the control unit 100 determines whether or not the bubble amount measured by the bubble measurement unit 103 is in a first reference range.

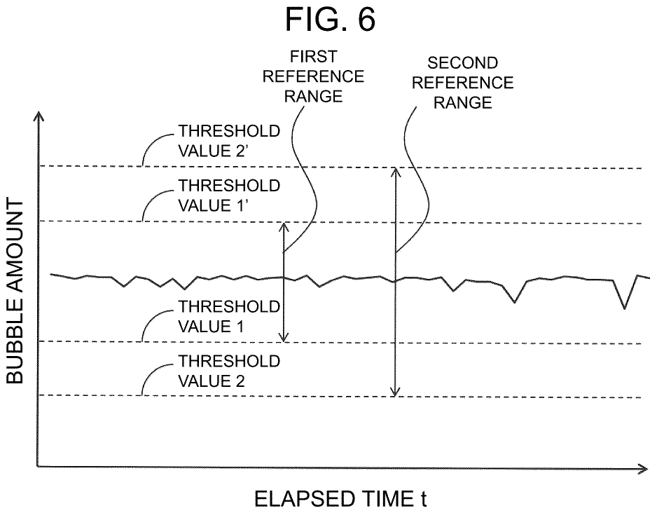

FIG. 6 is a diagram for explaining reference ranges and threshold values of the bubble amount. As illustrated in FIG. 6, the first reference range, which is defined by a threshold value 1 and a threshold value 1′, and a second reference range, which includes the first reference range and is defined by a threshold value 2 and a threshold value 2′, are stored in the storage unit 107.

Returning to FIG. 8, in a case where the bubble amount measured by the bubble measurement unit 103 is in the first reference range (in a case where the determination in step S12 is affirmative), the control unit 100 finishes the process. In a case where the bubble amount is out of the first reference range (in a case where the determination in step S12 is negative), the process progresses to step S13.

In step S13, the control unit 100 determines whether or not the second substrate detection unit 102 detects the substrate W in the second module in which the step of the substrate process using the fine bubble liquid is performed.

In a case where the second substrate detection unit 102 detects the substrate W, it is notified, via the output unit 106, that the bubble amount of the fine bubble liquid is unstable (step S14), and the substrate process in the second module is stopped (step S15). This is because in a case where the second substrate detection unit 102 detects the substrate W, the adjustment of the bubble amount of the fine bubble liquid will not be made in time.

On the other hand, in a case where the second substrate detection unit 102 does not detect the substrate W (in a case where the determination in step S13 is negative), the control unit 100 sprays the fine bubble liquid from the spray nozzle 41b, thereby starts the dummy dispensation of the fine bubble liquid (step S16), and performs a process for controlling the bubble amount in accordance with the measurement result of the bubble amount measured by the bubble measurement unit 103 (step S17).

When the control of the bubble amount is completed, the control unit 100 finishes the dummy dispensation of the fine bubble liquid (step S18).

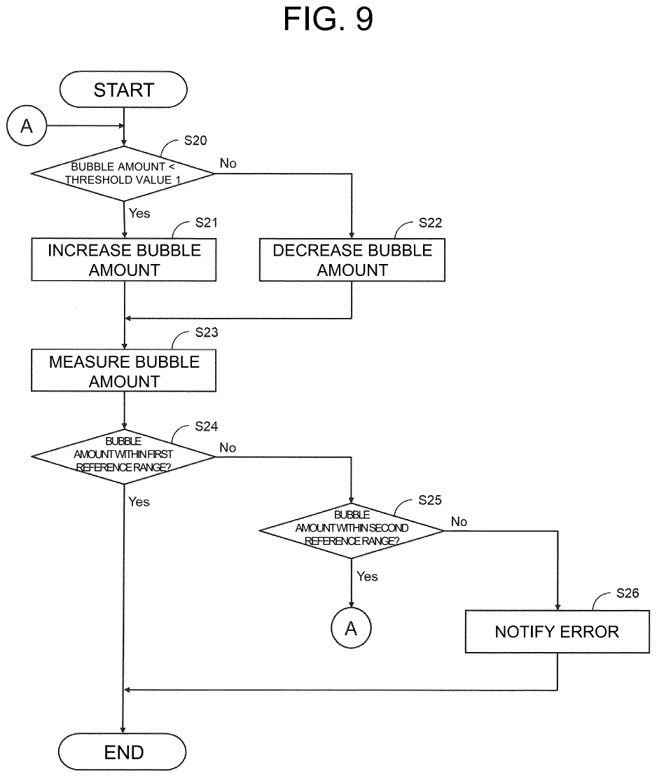

Next, a description will be made about one example of an action for controlling the bubble amount in accordance with the measurement result of the bubble amount measured by the bubble measurement unit 103. FIG. 9 is a flowchart illustrating one example of an action of control of the bubble amount (step S17), which is illustrated in FIG. 8.

First, the control unit 100 determines whether or not the bubble amount measured by the bubble measurement unit 103 is smaller than the threshold value 1 (see FIG. 6) (step S20).

In a case where the bubble amount measured by the bubble measurement unit 103 is smaller than the threshold value 1 (in a case where the determination in step S20 is affirmative), because this indicates a state where the bubble amount of the fine bubble liquid is smaller than a reference value, the control unit 100 gives an instruction for increasing the bubble amount to the fine bubble liquid supply device 40 (step S21).

On the other hand, in a case where the determination in step S20 is negative, this means that the bubble amount measured by the bubble measurement unit 103 is greater than the threshold value 1′ (see FIG. 6). Because this means that the bubble amount of the fine bubble liquid is greater than the reference value, the control unit 100 gives an instruction for decreasing the bubble amount to the fine bubble liquid supply device 40 (step S22).

After the bubble amount in the fine bubble liquid is adjusted in such a manner, the control unit 100 again measures the bubble amount of the fine bubble liquid by the bubble measurement unit 103 (step S23).

The control unit 100 determines whether or not the bubble amount of the fine bubble liquid, which is measured by the bubble measurement unit 103, is in the first reference range (step S24) and finishes the process in a case where the determination is affirmative.

On the other hand, in a case where it is determined that the bubble amount of the fine bubble liquid, which is measured by the bubble measurement unit 103, is out of the first reference range (in a case where the determination in step S24 is negative), the control unit 100 determines whether or not the bubble amount is in the second reference range (see FIG. 6) (step S25). In a case where the determination is affirmative, the process returns to step S20.

On the other hand, in a case where the bubble amount is out of the second reference range (in a case where the determination in step S25 is negative), this means that the control of the bubble amount is not normally achieved, and there is a possibility that an abnormality is present in the fine bubble liquid supply device 40 or the piping. Consequently, in this case, the control unit 100 notifies that an error is occurring to the user of the substrate processing device 1 via the output unit 106.

In the above configuration, in the step of the substrate process using the fine bubble liquid, a more stable fine bubble liquid can be supplied to a device.

An arbitrary part or all of function units described in the present specification may be implemented by a program. Programs mentioned in the present specification may be distributed while being recorded in computer-readable recording media in a non-transitory manner, may be distributed via a communication line (including wireless communication) such as the Internet, or may be distributed in a state where the programs are installed in arbitrary terminals.

A person having ordinary skill in the art might be able to conceive additional effects and various modifications of the present disclosure based on the above descriptions; however, aspects of the present disclosure are not limited to the above-described individual embodiments. Various additions, changes, and partial omissions are possible without departing from the scope of the conceptual ideas and gist of the present disclosure that are derived from contents and equivalents thereof which are defined by the claims.

For example, an article described as one device (or member and the same applies to the following) (including an article drawn as one device in the drawings) in the present specification may be implemented by a plurality of devices. Conversely, articles described as a plurality of devices (including articles drawn as a plurality of devices in the drawings) in the present specification may be implemented by one device. Alternatively, a part or all of means or functions that are assumed to be included in a certain device (for example, a server) may be included in another device (for example, a terminal device).

Not all of items described in the present specification are essential requirements. In particular, it can be said that items that are described in the present specification but not described in the claims are arbitrary additional items.

It should be noted that the present applicant only knows the known disclosure of the literature mentioned as the literature of the related art in the present specification and solving the problems in the known disclosure in the above literature is not necessarily set as an object of the present disclosure. An object to be solved by the present disclosure should be acknowledged taking into consideration the whole present specification. For example, in a case where the present specification has a description indicating that a specific configuration exhibits a predetermined effect, it can be said that a problem, which is reciprocally related with the predetermined effect, can be solved. However, it is not necessarily meant that such a specific configuration is set as an essential requirement.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions. This application claims the benefit of Japanese Patent Applications No. 2024-229914, filed Dec. 26, 2024, which is hereby incorporated by reference herein in its entirety.

1. A substrate processing device comprising:
a first substrate detection unit configured to detect a substrate in a first module to be used in a first process;
a bubble measurement unit configured to measure a bubble amount in piping, which supplies a fine bubble liquid to a second module to be used in a second process subsequent to the first process, in response to detection of the substrate by the first substrate detection unit; and
a control unit configured to control the bubble amount in accordance with a measurement result by the bubble measurement unit.

2. The substrate processing device according to claim 1, wherein
the bubble measurement unit has a light emission unit, which emits light toward the fine bubble liquid in the piping, and a light reception unit, which receives the light transmitted through the fine bubble liquid, and measures the bubble amount in accordance with a received light amount of light received by the light reception unit.

3. The substrate processing device according to claim 2, wherein
the control unit uses, as the bubble amount, a result of conversion of the received light amount into the number of bubbles.

4. The substrate processing device according to claim 1, wherein
the control unit controls the bubble amount in a case where the bubble amount measured by the bubble measurement unit exceeds a reference range.

5. The substrate processing device according to claim 1, further comprising
a second substrate detection unit configured to detect the substrate in the second module, wherein
in a case where the second substrate detection unit detects the substrate, the control unit does not control the bubble amount and notifies that the bubble amount is unstable.

6. A substrate processing method comprising:
detecting a substrate in a first module to be used in a first process;
measuring a bubble amount in piping, which supplies a fine bubble liquid to a second module to be used in a second process subsequent to the first process, in response to detection of the substrate in the first module; and
controlling the bubble amount in accordance with a measurement result of the bubble amount.

7. A non-transitory computer-readable medium storing a program for causing a computer to execute a method comprising:
detecting a substrate in a first module to be used in a first process;
measuring a bubble amount in piping, which supplies a fine bubble liquid to a second module to be used in a second process subsequent to the first process, in response to detection of the substrate in the first module; and
controlling the bubble amount in accordance with a measurement result of the bubble amount.
